(19) United States
(12) Patent Application Publication
(10) Pub. No.: US 2024/0040799 A1
(43) Pub. Date: Feb. 1, 2024

(54) FERROELECTRIC TUNNEL JUNCTION DEVICE

(71) Applicant: Taiwan Semiconductor Manufacturing Company, Ltd., Hsinchu (TW)

(72) Inventors: Kuen-Yi Chen, Hsinchu (TW); Fu-Hai Li, Tainan (TW); Yi Ching Ong, Hsinchu (TW); Kuo-Ching Huang, Hsinchu (TW); Yi-Hsuan Chen, Taoyuan (TW); Yu-Sheng Chen, Taoyuan (TW)

(73) Assignee: Taiwan Semiconductor Manufacturing Company, Ltd., Hsinchu (TW)

(21) Appl. No.: 17/815,601

(22) Filed: Jul. 28, 2022

(51) Int. Cl. H01L 27/11507

(52) U.S. Cl. CPC H01L 27/11507

(57) ABSTRACT

A memory device includes a transistor device; a memory cell electrically coupled to a source or drain of the transistor device, wherein the memory cell includes an FJT structure; and a heating structure formed around the memory cell on a plurality of sides. The FJT structure includes a first conductive electrode having sidewalls that extend in a vertical direction to a first elevation level, a second conductive electrode having sidewalls that extend in the vertical direction to the first elevation level, and a switching barrier disposed between the first conductive electrode and the second conductive electrode and having sidewalls that extend in the vertical direction to the first elevation level, wherein the vertically extending sidewalls of the first conductive electrode, the second conductive electrode, and the switching barrier terminate at the first elevation level. The switching barrier includes ferroelectric (Fe) material that may be polarized to store information.

### BACKGROUND

A conventional ferroelectric tunnel junction (FTJ) is a tunnel junction which includes two metal electrodes that are separated by a thin ferroelectric layer. The direction (also referred to as orientation) of electrical polarization of the ferroelectric layer can be switched by an electric field applied. The electrical resistance of the FTJ, also referred to as the tunneling electro resistance (TER) of the FTJ, is determined by the orientation of the electric polarization of the ferroelectric layer. For example, by changing the electrostatic potential (e.g., voltage) profile across the ferroelectric barrier, the FTJ may change from a high-resistance state (HRS) to a low-resistance state (LRS), or vice versa. The tunneling current of the FTJ, which is inversely proportional to the programmable TER of the FTJ, may be used to represent different states (e.g., “0” or “1”) of the memory device.

Due to the ability to program (e.g., set) the tunneling electro resistance of the FTJ with different voltages, there has been increased interest in FTJ-based non-volatile memory devices. However, there are many challenges in forming FTJs suitable for memory devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram that illustrates a perspective view of an example semiconductor structure, in accordance with some embodiments;

FIG. 1B, is a diagram that illustrates a perspective view of an example memory cell layer, in accordance with some embodiments;

FIG. 2A is a diagram that depicts a perspective view of an example memory device in a semiconductor structure at a fabrication stage before crystallization of Fe material of a FTJ device in the memory device, in accordance with some embodiments;

FIG. 2B is a diagram that depicts a perspective view of an example memory device in a semiconductor structure at a fabrication stage after crystallization of the Fe material of the FTJ device, in accordance with some embodiments;

FIG. 3A is a plot of I-V measurements taken of an exemplary FTJ device after Fe material crystallization, in accordance with some embodiments;

FIGS. 3B and 3C are schematic circuit diagrams of an exemplary memory device that includes an FTJ device after Fe material crystallization, in accordance with some embodiments;

FIGS. 4A and 4B are top views of example spiral micro-heater structures that may be employed in a semiconductor device to crystalize Fe material in multiple FJT devices in parallel, in accordance with some embodiments;

FIG. 5A is a schematic diagram that illustrates a role of an interfacial layer in a switching barrier, in accordance with some embodiments;

FIG. 5B is a schematic diagram that illustrate behavior in FTJ structures that include an interfacial layer, at a positive remanent polarization (+Pr), in accordance with some embodiments;

FIG. 5C is a schematic diagram that illustrate behavior in FTJ structures that include an interfacial layer at a negative remanent polarization (−Pr), in accordance with some embodiments;

FIGS. 6A and 6B illustrate example routing configurations for providing access to the top electrode and bottom electrode of a vertical FJT device), in accordance with some embodiments; and

FIG. 7 is a process flow chart depicting an example method for fabricating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments provided herein provide for forming a ferroelectric tunnel junction (FTJ) device at back end of line (BEOL) processing with an ultra-thin ferroelectric thin film. Processing that embeds FTJ devices in CMOS BEOL may constrain the thermal energy that is needed to crystallize the ferroelectric material of the FTJ device. Typically, a higher thermal annealing temperature is needed for thinner ferroelectric films. Therefore, ferroelectric films may be limited to a thickness of 5 nanometers (nm) in order to have an annealing temperature of less than 450° C. for crystallization.

Embodiments herein make use of a built-in heater to crystallize the ferroelectric (Fe) material without using high thermal annealing temperatures that may negatively affect other BEOL devices. The absence of high annealing temperatures provides a larger process window. Also, embodiments herein provide for a cost reduction in processing. Also, the FTJ memory cell may be provided with increased sensing current.

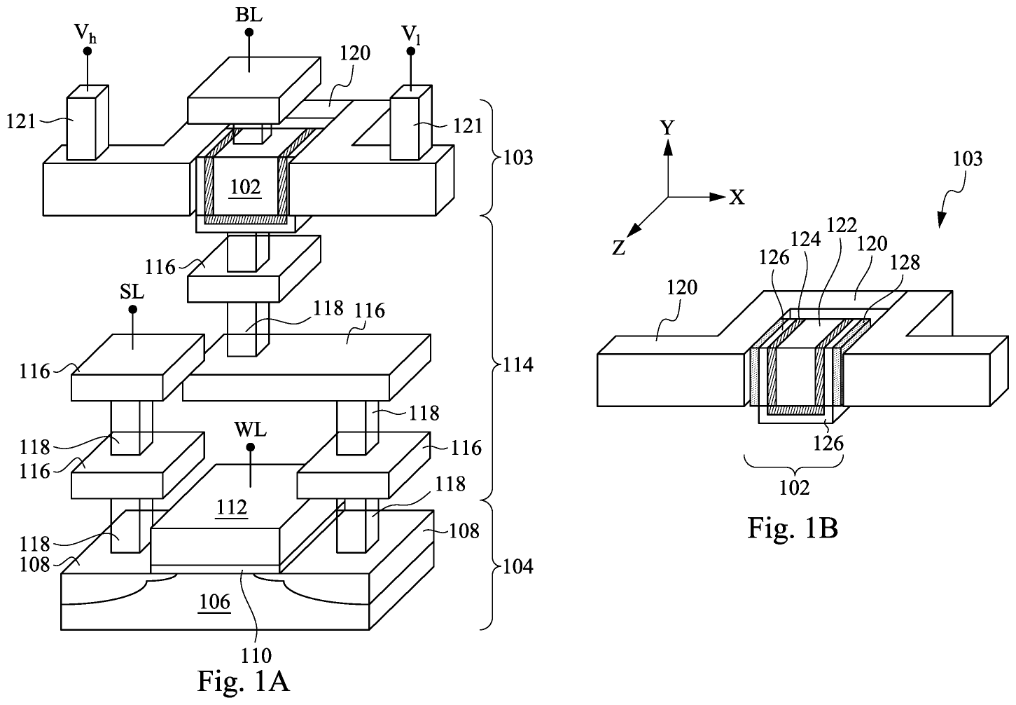

FIG. 1A illustrates a perspective view of an example semiconductor structure 100 according to some embodiments. Note that for clarity, not all features of the semiconductor structure 100 are illustrated in FIG. 1A and FIG. 1A may illustrate only a portion of the semiconductor structure formed. The semiconductor structure 100 includes a memory cell 102 in a memory cell layer 103 that is electrically connected to a transistor device 104. The memory cell 102 includes a ferroelectric tunnel junction (FTJ) structure. The memory cell 102 (also referred to herein as FTJ device) and the transistor device 104 collectively form a ferroelectric random-access memory (FeRAM). The FeRAM stores information using the spontaneous polarization of Fe material in the memory cell 102. The FJT device 102 may be a memory cell of a memory device (e.g., a non-volatile memory device) with a 1T1FTJ structure, where T stands for transistor, and FTJ stands for ferroelectric tunnel junction. As shown, a bit line (BL), select line (SL), and write line (WL) are electrically connected to the FeRAM for signal communication as desired.

The example transistor device 104 is a metal-oxide-semiconductor field effect transistor (MOSFET) device embedded in a dielectric layer (not shown) on a substrate. The example MOSFET device 104 includes a p-well 106, n+ regions 108 representing source/drain regions of the FET, an oxide layer 110 over a channel region of the FET, and a gate layer 112 over the oxide layer 110. In this example, the MOSFET device 104 is an n-FET device. In other examples, the MOSFET device 104 may be a p-FET device that includes an n-well and p+ regions representing source/drain regions of the FET. In certain embodiments, the transistor device 104 is formed by front-end-of-line (FEOL) processes and may be considered as an FEOL device.

The substrate may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the substrate and may be interconnected by interconnect structures formed by, for example, metallization patterns in one or more dielectric layers over the substrate. FIG. 1A only illustrates a portion of the device that includes the FTJ device 102 and the transistor 104.

In some embodiments, the semiconductor structure 100 further includes, but is not limited thereto, other types of transistors, capacitors, resistors, or the like. The transistor device 104 is electrically connected to the memory cell 102 via an interconnection structure 114. In certain embodiments, the interconnection structure 114 is formed by middle-end-of-line (MEOL) processes and may be considered as an MEOL structure. In some embodiments, the interconnection structure 114 includes conductive lines 116 and conductive vias 118 embedded in an insulating layer (not shown) for interconnecting the transistor device 104 and the memory cell 102, and for electrically connecting the transistor device 104 with other above layers. Although only one transistor device 104 is shown in FIG. 1A, it is well understood that multiple tiers or layers of transistors may be formed.

The memory cell layer 103 is formed by back-end-of-line (BEOL) processes and may be considered as a BEOL layer. The memory cell layer 103 includes a micro-heater structure 120 and vias 121 for providing connection to voltages Vₕ and Vₗ for actuating the micro-heater. The micro-heater structure 120 can essentially be a metal coil. The micro-heater structure 120 provides a heating source for crystalizing the Fe material in the FJT device 102 so that a high annealing heating temperature does not have to be applied during the BEOL processes to crystalize the Fe material. Because a separate micro-heater structure 120 is used to crystalize the Fe material in the FJT device 102, smaller dimensions for components of the FJT device 102 may be used. Use of the micro-heater structure 120 to crystalize the Fe material in the FJT device 102 can reduce process time without long-term annealing. The micro-heater structure 120 provides selective local heating and is a BEOL compatible process. Use of the micro-heater structure 120 can extend FTJ scalability—it can allow for thickness <4 nanometers (nm) with a large read signal.

FIG. 1B illustrates a perspective view of an example memory cell layer 103. The example memory cell layer 103 includes a micro-heater structure 120, a vertical FJT device 102, and shallow trench isolation (STI) 128.

The example micro-heater structure 120 is a conductive electrode with a high melting temperature. In some embodiments the melting temperature is greater than or equal to (>=) 800° C. The micro-heater structure 120 may be formed from a conductive material, such as Pt, Cr, Au, Mo, W, Ta, Ti, poly-Si etc. A suitable deposition method, such as ALD, may be used to form the micro-heater structure 120.

The STI 128 is formed between the FJT device 102 and the micro-heater structure 120, and electrically isolates the FJT device 102 from the micro-heater structure 120. The STI 128 is formed from a dielectric oxide, such as SiO₂, etc. A suitable deposition method, such as ALD, may be used to form the STI 128.

The example vertical FJT device 102 includes a top electrode 122, a switching barrier 124, and a bottom electrode 126. The FJT device 102 is referred to as a vertical FJT device because the top electrode 122, the switching barrier 124, and the bottom electrode 126 all have sidewalls that extend vertically in the y-direction, are parallel to each other, and terminate at the same elevation level.

The top electrode 122 is a conductive electrode and is formed of suitable conductive material such as, a pure metal, refractory metal nitrides, conductive oxide, semiconductor, etc. A suitable formation method, such as atomic layer deposition (ALD), may be used to form the top electrode 122.

The switching barrier 124 is formed around parallel sidewalls of the top electrode 122 and along the bottom of the top electrode 122 to sandwich the top electrode 122 with a U-type shape cross-section. The switching barrier 124 includes Fe material (such as a ferroelectric oxide) and interfacial layer (IL) material. The Fe material is formed of a suitable ferroelectric material, such as perovskite, rutile, or orthorhombic thin film with sub 40 Å thickness. A suitable deposition method, such as ALD, may be used to form the ferroelectric material. The IL is formed of a suitable non-polar material, such as SiO₂, Al₂O₃, Ta₂O₅, TiO₂, TaON, etc. with sub 20 Å thickness. A suitable deposition method, such as ALD, may be used to form the IL.

The bottom electrode 126 is formed around parallel sidewalls of the switching barrier 124 and along the bottom of switching barrier 124 to sandwich the switching barrier 124 with a U-type shape cross-section. The bottom electrode 126 is formed of an electrically conductive material, such as pure metal, refractory metal nitrides, conductive oxide, and semiconductor. A suitable formation method, such as atomic layer deposition (ALD), may be used to form the bottom electrode 126. The bottom electrode 126 may be formed of a same material as the top electrode 122 or of a different material. All metal layers, such as the micro-heater structure 120, the top electrode 122, and the bottom electrode 126 may be formed from the same or different material.

The bottom electrode 126, the switching barrier 124, and the top electrode 122 may be collectively referred to as an MFIM structure, where M stands for the metal material (e.g., of electrode 126 or electrode 122), F stands for the ferroelectric material (e.g., of switching barrier 124), and I stands for the IL material (e.g., of switching barrier 124). The FTJ device 102 is a two-terminal device, with the bottom electrode 126 and the top electrode 122 functioning as the two terminals of the FTJ device 102.

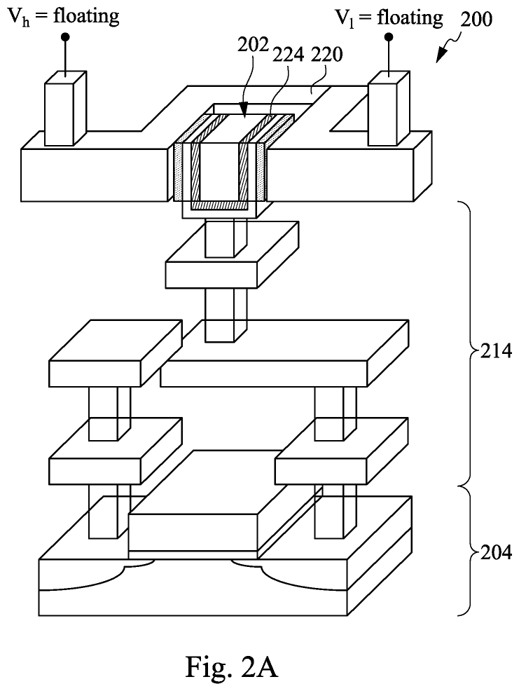

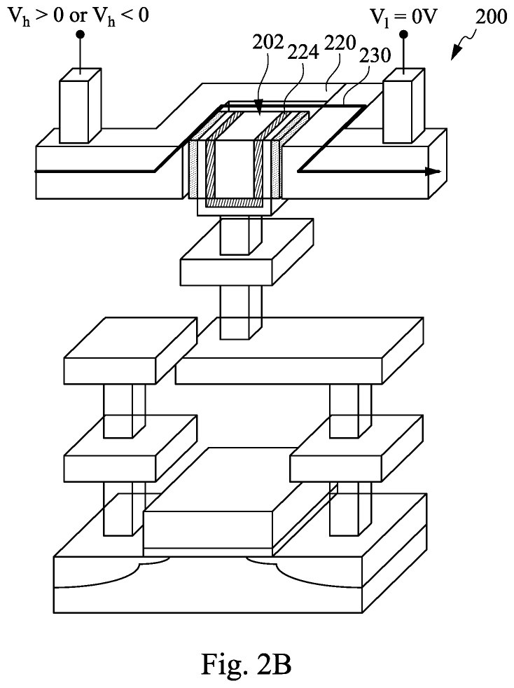

FIGS. 2A and 2B illustrates perspective views of an example memory device 200 in a semiconductor structure at a fabrication stage before crystallization of Fe material of a FTJ device in the memory device and after crystallization of the Fe material of the FTJ device. The example memory device 200 depicted in FIG. 2A includes an FJT memory cell 202, a micro-heater 220 formed around the FJT memory cell 202 on a plurality of sides, and a transistor device 204 coupled to the FJT memory cell 202 via an interconnection structure 214. The FJT memory cell 202 has the same structure as the memory cell 102 depicted in FIGS. 1A and 1B, including a switching barrier 224 formed of Fe material and interfacial layer (IL) material. At this stage of fabrication, the Fe material is in an amorphous, non-crystalized form, such as an amorphous Ferroelectric oxide. Also, at this stage of fabrication the voltage levels at both the Vₕ and Vₗ terminals of the micro-heater 220 are floating, and no current is flowing through the micro-heater 220.

FIG. 2B depicts the example memory device 200 at a later stage of fabrication. In this example, a voltage difference is created between the Vₕ and Vₗ terminals of the micro-heater 220 to cause a current 230 to flow through the micro-heater 220. In one embodiment, a positive or negative voltage level is applied to the Vₕ terminal, and a zero (or ground) voltage level is applied to the Vₗ terminal. In another embodiment, a positive or negative voltage level is applied to the Vₗ terminal, and a zero (or ground) voltage level is applied to the Vₕ terminal. The current 230 flow through the micro-heater 220 causes the micro-heater 220 to heat up (e.g., Joule-heating) and in turn to heat up the Fe material in the switching barrier 224. This localized heating can cause the Fe material (e.g., amorphous Fe oxide) in the switching barrier 224 to crystalize (e.g., into crystalized Fe oxide). This localized heating can be performed in a BEOL process without higher annealing temperature (e.g., >400° C.) that would affect the other BEOL device. This can be used to for an Fe layer thickness of sub 4 nm to enable sufficient sensing current without Fe response degradation due to poor crystallinity.

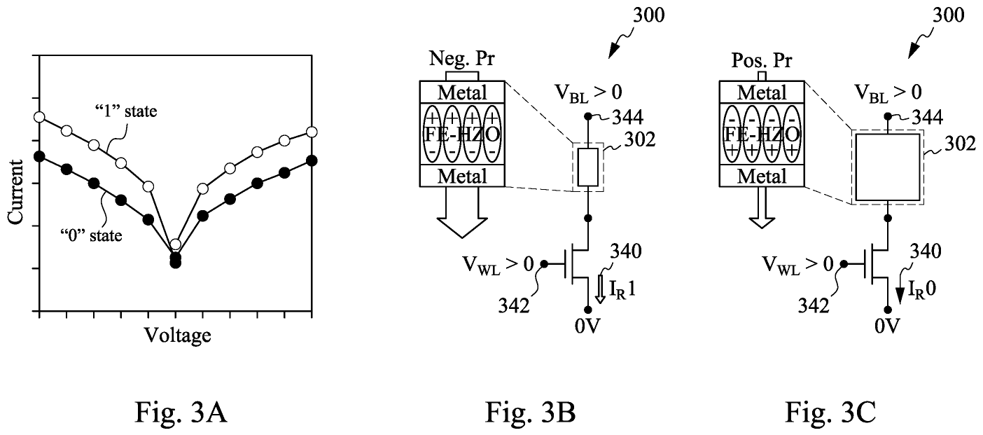

FIG. 3A is a plot of I-V measurements taken of an exemplary FTJ device (e.g., FJT device 202) after Fe material crystallization. As illustrated, at various voltage levels, a distinct current level difference is detectable, for example by a sense amplifier in a memory device, when the FTJ device is biased in a “1” state versus a “0” state. Thus, an exemplary FTJ device (e.g., FJT device 202) may be used as a memory cell in a memory device.

FIGS. 3B and 3C are schematic circuit diagrams of an exemplary memory device 300 that includes an FTJ device 302 (e.g., FJT device 202) after Fe material crystallization. In FIG. 3B, the FJT device 302 has been biased (e.g., through a memory write operation) to a “1” state and thus has a negative remanent polarization (Neg. Pr). This results in the Fe material having a smaller tunneling barrier, a low resistance, and a larger read current (I_{R}1) 340, when a sufficiently positive word line voltage V_{WL} is applied to the gate 342 of the transistor in the memory cell 300 and a sufficiently positive bit line voltage V_{BL} is applied to the source 344 of the transistor.

In FIG. 3C, the FJT device 302 has been biased (e.g., through a memory write operation) to a “0” state and thus has a positive remanent polarization (Pos. Pr). This results in the Fe material having a larger tunneling barrier, a high resistance, and a smaller read current (I_{R}0) 340, when a sufficiently positive word line voltage V_{WL} is applied to the gate 342 of the transistor in the memory cell 300 and a sufficiently positive bit line voltage V_{BL} is applied to the source 344 of the transistor.

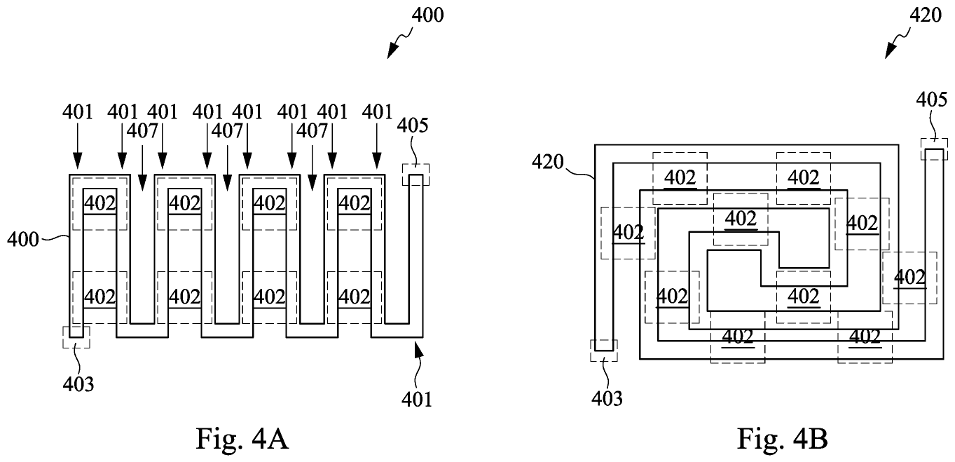

FIGS. 4A and 4B are top views of example spiral micro-heater structures that may be employed in a semiconductor device to crystalize Fe material in multiple FJT devices in parallel. FIG. 4A illustrates a first spiral heater structure 400 in which a plurality of FJT devices 402 (eight in this example) may be heated in parallel. In this example, the spiral heater structure 400 has a plurality of columns of heater lines 401 that are interconnected to form a contiguous structure. Each column of heater lines 401 is closely adjacent to a side of an FJT device 402. In this example, each column of heater lines 401 is closely adjacent on one side to an FJT device 402. In other examples, each column of heater lines 401 may be closely adjacent on a plurality of sides to an FJT device 402 (e.g., FJT devices 402 may be disposed between openings 407 in the spiral heater structure 400. At ends of the first spiral heater structure 400 are metal pads 403, 405 at which differing Vₕ and Vₗ voltage levels may be applied to cause a current to flow through each of the columns of heater lines 401. A current flow through the columns of heater lines 401 may cause the columns of heater lines 401 to heat up (e.g., Joule-heating) and in turn to heat up the Fe material in the FJT devices 402. This localized heating can cause the Fe material (e.g., amorphous Fe oxide) in the FJT devices 402 to crystalize (e.g., into crystalized Fe oxide). This localized heating can be performed in a BEOL process without higher annealing temperature (e.g., >400° C.) that would affect the other BEOL device. This can be used to for an Fe layer thickness of sub 4 nm to enable sufficient sensing current without Fe response degradation due to poor crystallinity.

FIG. 4B illustrates a second spiral heater structure 420 in which a plurality of FJT devices 402 (ten in this example) may be heated in parallel. In this example, the spiral heater structure 420 spirals in a pattern that allows more FJT devices 402 to be heated in parallel than in the first spiral heater structure 400. Each FJT devices 402 is closely adjacent to the spiral heater structure 420 on two sides. At ends of the first spiral heater structure 420 are metal pads 403, 405 at which differing Vₕ and Vₗ voltage levels may be applied to cause a current to flow through the spiral heater structure 420. A current flow through the spiral heater structure 420 may cause the spiral heater structure 420 to heat up (e.g., Joule-heating) and in turn to heat up the Fe material in the FJT devices 402. This localized heating can cause the Fe material (e.g., amorphous Fe oxide) in the FJT devices 402 to crystalize (e.g., into crystalized Fe oxide). This localized heating can be performed in a BEOL process without higher annealing temperature (e.g., >400° C.) that would affect the other BEOL device. This can be used to for an Fe layer thickness of sub 4 nm to enable sufficient sensing current without Fe response degradation due to poor crystallinity.

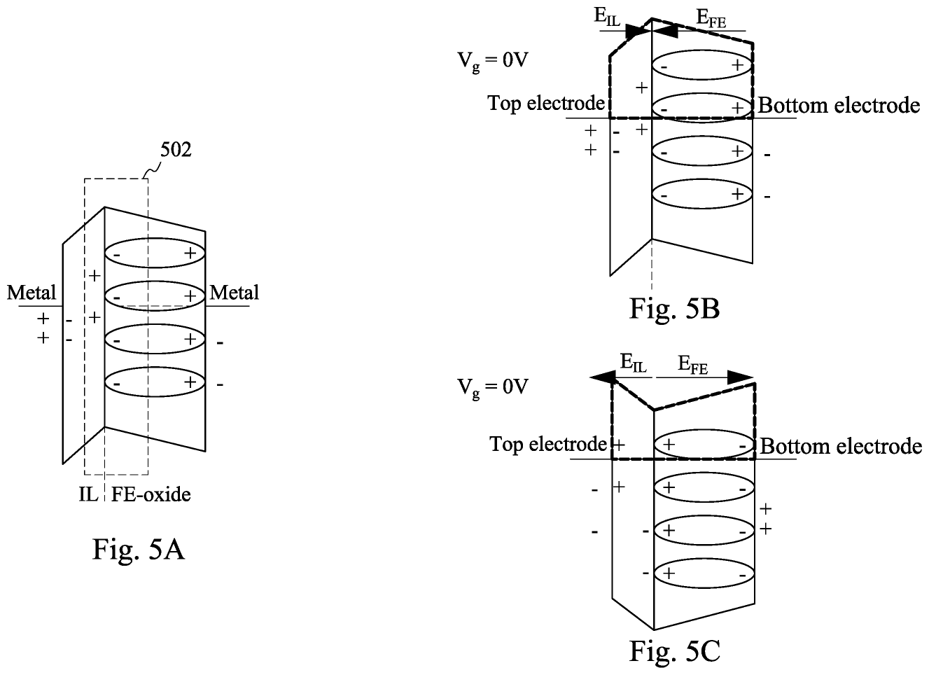

FIG. 5A is a schematic illustrating a role of an interfacial layer in a switching barrier (e.g., switching barrier 124). In a MFM configuration (e.g., when an interfacial layer is not used in the switching barrier of an FJT structure) perfect Pr screening may occur. The magnitude of polarization at E=0 is called remanent polarization (Pr). Perfect Pr screening does not allow for the FJT structure to be biased to a “0” or “1” state for use as a memory cell. By use of a MFIM configuration (e.g., Metal, IL, Fe-oxide, Metal structure) imperfect Pr screening may occur. This can allow the FJT structure to be biased to a “0” or “1” state for use as a memory cell. As illustrated in FIG. 2A, a band bend forms in the area 502 at the barrier between the IL and the Fe material when the FJT structure is biased. This occurs because the net charge is not equal to zero and the electric field is not equal to zero leading to band bending by polarization-modulated barrier shape.

FIGS. 5B and 5C illustrate behavior in FTJ structures that include an interfacial layer, at a positive remanent polarization (+Pr) and at a negative remanent polarization (−Pr). As illustrated in FIG. 5B, at a positive remanent polarization (+Pr) (e.g., when an FJT structure is biased to a “0” state), a negative electric field (E_{PE}) exists in the Fe, there is an effective barrier height (BH) increase, and the FJT device is put in a high-resistance state (HRS). In the HRS, there is band bending in a first direction.

As illustrated in FIG. 5C, at a negative remanent polarization (−Pr) (e.g., when an FJT structure is biased to a “1” state), a positive electric field (E_{FE}) exists in the Fe, there is an effective barrier height (BH) decrease, and the FJT device is put in a low-resistance state (LRS). In the LRS, there is band bending in a second direction different from the first direction.

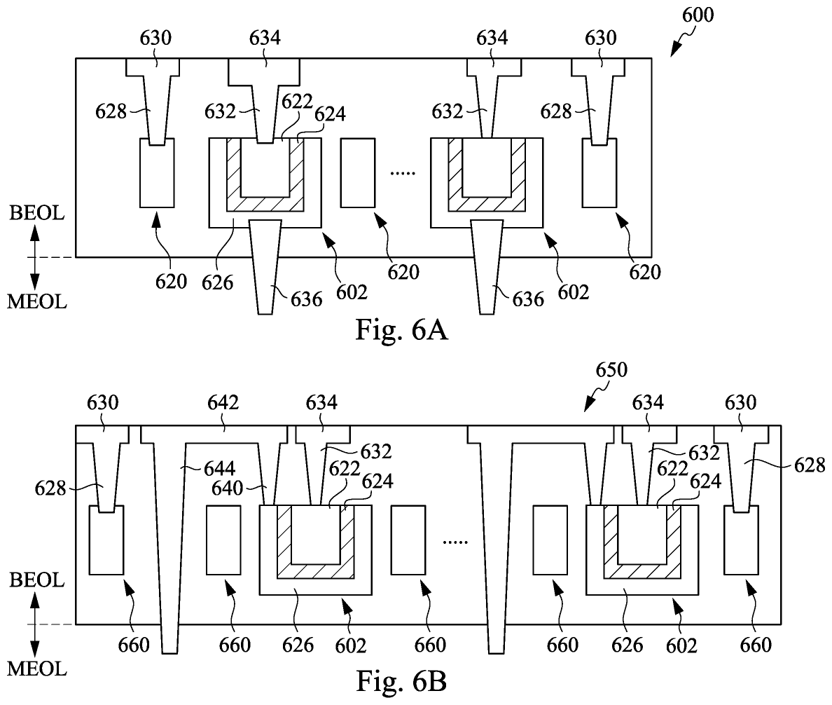

FIGS. 6A and 6B illustrate example routing configurations for providing access to the top electrode and bottom electrode of a vertical FJT device. In the example of FIG. 6A, a semiconductor structure 600 includes a plurality of vertical FJT devices 602 and a micro-heater assembly 620. Each of the plurality of vertical FJT devices 602 includes a top electrode 622, a switching barrier 624, and a bottom electrode 626. Vias 628 and metal lines 630 are provided to provide Vₕ and Vₗ terminals for application of a voltage difference to cause the micro-heater assembly 620 to heat up to crystalize the Fe material in the switching barrier 624. A via 632 and metal line 634 are provided above the top electrode 622 to provide a connection point for one terminal of the memory cell formed by the FJT device 602. A via 636 is provided below the bottom electrode 626 to provide a connection point for a second terminal of the memory cell formed by the FJT device 602. In this example, the via 636, which provides a connection point for the second terminal of the memory cell formed by the FJT device 602, is formed before formation of the vertical FJT device.

In the example of FIG. 6B, a semiconductor structure 650 includes a plurality of vertical FJT devices 602 and a micro-heater assembly 660. Each of the plurality of vertical FJT devices 602 includes a top electrode 622, a switching barrier 624, and a bottom electrode 626. Vias 628 and metal lines 630 are provided to provide Vₕ and Vₗ terminals for application of a voltage difference to cause the micro-heater assembly 660 to heat up to crystalize the Fe material in the switching barrier 624. A via 632 and metal line 634 are provided above the top electrode 622 to provide a connection point for one terminal of the memory cell formed by the FJT device 602. A via 640 is provided above the bottom electrode 626, which is connected to a metal line 642 above the bottom electrode 626, which in turn is connected to a via 644 which connects the bottom electrode 626 to lower layers in the semiconductor structure 650. The combination of the via 640, the metal line 642, and the via 644 provide a connection point for a second terminal of the memory cell formed by the FJT device 602. In this example, the connection point for the second terminal of the memory cell formed by the FJT device 602 may be formed after formation of the vertical FJT device.

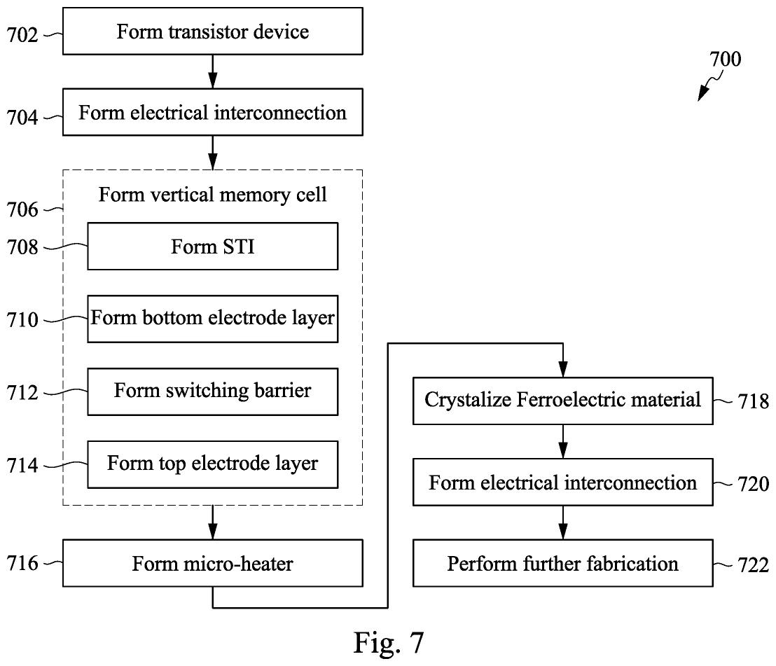

FIG. 7 is a flow chart depicting an example method 700 for fabricating a semiconductor device. Cross-referencing FIG. 7 and FIGS. 1A-1B, 2A-2B, and 6A-6B, the example method 700 includes at operation 702 forming a transistor device 104, such as a MOSFET embedded in a dielectric layer (not shown) on a substrate. The MOSFET may be an n-channel or p-channel MOSFET formed in accordance with complementary MOS (CMOS) processes. In certain embodiments, the transistor device 104 is formed by front-end-of-line (FEOL) processes and may be considered as a FEOL devices. In some embodiments, the formation of the transistor device 104 includes forming a p-well 106, n+ regions 108 representing source/drain regions of the FET, an oxide layer 110 over a channel region of the FET, and a gate layer 112 over the oxide layer 110. In addition, conductive vias 118 are formed on the source and drain regions 108. In some embodiments, the gate layer 112 includes a gate electrode and a gate dielectric layer.

In some embodiments, the dielectric layer may be referred as an interlayer dielectric (ILD) layer. In some embodiments, the material of the dielectric layer includes silicon oxide, silicon nitride, silicon oxynitride, phosphosilicate glass (PSG), borosilicate glass (BSG), boron-doped phosphosilicate glass (BPSG), or low-k materials. The dielectric layer may be formed by any acceptable deposition process, such as spin coating, chemical vapor deposition (CVD), or other suitable methods.

At operation 704, method 700 includes forming an interconnection structure 114 that provides electrical connections to and from the transistor device 104. Forming the interconnection structure 114 includes forming conductive lines 116 and conductive vias 118 that electrically connect to the transistor device 104. In some embodiments, the material of the conductive lines 116 and the conductive vias 118 may include a metal, such as copper, titanium, tungsten, aluminum, or a combination thereof. The conductive lines 116 and the conductive vias 118 may be formed by CVD or plating.

At operation 706, method 700 includes forming a vertical memory cell 102. Forming the vertical memory cell may include patterning and deposition operations to: form STI 128 at operation 708, form a bottom electrode layer 126 at operation 710, form a switching barrier 124 at operation 712, and form a top electrode 122 at operation 714.

At operation 716, method 700 includes forming a micro-heater 120 around a plurality of sides of the vertical memory cell 102. The micro-heater 120 may be formed around a single vertical memory cell or it may be formed around a plurality of vertical memory cells.

The top electrode 122, bottom electrode layer 126, and micro-heater 120 may be formed of suitable conductive material such as, a pure metal, refractory metal nitrides, conductive oxide, semiconductor, etc. The top electrode 122, bottom electrode layer 126, and micro-heater 120 may be formed of the same or different material. A suitable formation method, such as atomic layer deposition (ALD), may be used to form the top electrode 122, bottom electrode layer 126, and micro-heater 120.

The switching barrier 124 includes Fe material and interfacial layer (IL) material. The Fe is formed of a suitable ferroelectric material, such as perovskite, rutile, or orthorhombic thin film with sub 40 Å thickness. A suitable deposition method, such as ALD, may be used to form the ferroelectric material. The IL is formed of a suitable non-polar material, such as SiO₂, Al₂O₃, Ta₂O₅, TiO₂, TaON, etc. with sub 20 Å thickness. A suitable deposition method, such as ALD, may be used to form the IL.

The switching barrier 124 may be formed in different stages. In some embodiments, the Fe is formed using a suitable deposition method and afterward the IL is formed using a suitable deposition method. In some embodiments, the IL is formed using a suitable deposition method and afterward the Fe is formed using a suitable deposition method.

The bottom electrode layer 126 and micro-heater 120 may be formed in parallel or in different orders. Although example method 700 depicts operation 716 as occurring after operation 706, in some examples operation 716 may occur in parallel with operation 706. In some examples, operation 716 may occur before operation 706. In some examples, operation 716 may occur after operation 706.

After formation of the vertical memory cell 102 and the micro-heater 120, the example method 700 includes, at operation 718, crystalizing the ferroelectric material in the memory cell 102 using the micro-heater 120. Crystalizing the ferroelectric material includes applying a voltage difference between the Vₕ and Vₗ terminals of the micro-heater 220 to cause a current 230 to flow through the micro-heater 220. In one embodiment, a positive or negative voltage level is applied to the Vₕ terminal, and a zero (or ground) voltage level is applied to the Vₗ terminal. In another embodiment, a positive or negative voltage level is applied to the Vₗ terminal, and a zero (or ground) voltage level is applied to the Vₕ terminal. The current 230 flow through the micro-heater 220 causes the micro-heater 220 to heat up (e.g., Joule-heating) and in turn to heat up the Fe material in the switching barrier 224. This localized heating can cause the Fe material (e.g., amorphous Fe oxide) in the switching barrier 224 to crystalize (e.g., into crystalized Fe oxide). This localized heating can be performed in a BEOL process without higher annealing temperature (e.g., >400° C.) that would affect the other BEOL device. This can be used to for an Fe layer thickness of sub 4 nm to enable sufficient sensing current without Fe response degradation due to poor crystallinity.

The method 700 may further include, at operation 720, forming an interconnection over the memory cell 102. The interconnections include more metallization structures including conductive vias (e.g., 628, 632, 640, 644) and conductive lines (e.g., 630, 634, 642). The method 700 may include, at operation 722, further processing steps to complete an integrated circuit.

In the foregoing examples, the transistor was a planar transistor, such as an FET or MOSFET. In other examples, non-planar transistors, such as FINFET may be used. As with the other method embodiments and exemplary devices discussed herein, it is understood that parts of the semiconductor devices may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and or other logic devices, etc., but is simplified for better understanding of concepts of the present disclosure. In some embodiments, exemplary devices include a plurality of semiconductor devices (e.g., transistors), including PFETs, NFETs, etc., which may be interconnected.

In various embodiments, a ferromagnetic tunnel junction (FTJ) device includes a heating structure formed around an FJT structure on a plurality of sides. The FJT structure includes a first conductive electrode having sidewalls that extend in a vertical direction to a first elevation level, a second conductive electrode having sidewalls that extend in the vertical direction to the first elevation level, and a switching barrier disposed between the first conductive electrode and the second conductive electrode and having sidewalls that extend in the vertical direction to the first elevation level. The vertically extending sidewalls of the first conductive electrode, the second conductive electrode, and the switching barrier terminate at the first elevation level. The switching barrier includes ferroelectric (Fe) material that may be polarized to store information.

In certain embodiments of the FJT device, the heating structure and the FJT structure are formed in a BEOL (back-end-of-line) process.

In certain embodiments of the FJT device, the switching barrier includes an Fe material plus an interfacial layer (IL) material.

In certain embodiments of the FJT device, the Fe material is formed with sub 40 Å thickness.

In certain embodiments of the FJT device, the Fe material includes perovskite, rutile, or orthorhombic thin film.

In certain embodiments of the FJT device, the IL material is formed of a non-polar material with sub 20 Å thickness.

In certain embodiments of the FJT device, the IL material includes SiO₂, Al₂O₃, Ta2O5, TiO2, or TaON.

In certain embodiments of the FJT device, the Fe material of the switching barrier is crystalized by heat emitted from the heating structure.

In certain embodiments of the FJT device, the heating structure emits heat responsive to a current flow through the heating structure.

In certain embodiments of the FJT device, the heating structure is a conductive electrode with a melting temperature greater than or equal to 800° C.

In certain embodiments of the FJT device, shallow trench isolation (STI) is disposed between the heating structure and the FJT structure.

In certain embodiments of the FJT device, the switching barrier is formed around parallel sidewalls of the first conductive electrode and along a bottom of the first conductive electrode to sandwich the first conductive electrode.

In certain embodiments of the FJT device, the second conductive electrode is formed around parallel sidewalls of the switching barrier and along the bottom of the switching barrier to sandwich the switching barrier.

In various embodiments, a semiconductor fabrication method includes: forming a second conductive electrode over an interconnection structure, the second conductive electrode having sidewalls that extend vertically to a first elevation; forming a switching barrier within a gap in the second conductive electrode, the switching barrier having sidewalls that extend vertically to the first elevation, the switching barrier including ferroelectric material; forming a first conductive electrode within a gap in the switching barrier, the first conductive electrode having sidewalls that extend vertically to the first elevation; and heating the Fe material using a heater structure formed around a plurality of sides of the second conductive electrode to crystalize the Fe material, wherein the crystalized Fe material may be polarized to store information.

In certain embodiments, the method further includes forming the heater structure, and the second conductive electrode, the switching barrier, the first conductive electrode, and the heater structure are formed in a BEOL (back-end-of-line) process.

In certain embodiments of the method, the switching barrier includes an Fe material plus an interfacial layer (IL) material.

In certain embodiments of the method, the Fe material is formed with sub 40 Å thickness.

In certain embodiments of the method, the Fe material includes perovskite, rutile, or orthorhombic thin film.

In certain embodiments of the method, the IL material is formed of a non-polar material with sub 20 Å thickness.

In certain embodiments of the method, the IL material includes SiO₂, Al₂O₃, Ta₂O₅, TiO₂, or TaON.

In certain embodiments of the method, the Fe material of the switching barrier is crystalized by heat emitted from the heating structure.

In certain embodiments of the method, the heating structure emits heat responsive to a current flow through the heating structure.

In certain embodiments of the method, the heating structure is a conductive electrode with a melting temperature greater than or equal to 800° C.

In certain embodiments, the method further includes forming shallow trench isolation (STI) between the heating structure and the second conductive electrode.

In various embodiments, a memory device includes a transistor device; a memory cell electrically coupled to a source or drain of the transistor device, wherein the memory cell includes an FJT structure; and a heating structure formed around the memory cell on a plurality of sides. The FJT structure includes a first conductive electrode having sidewalls that extend in a vertical direction to a first elevation level, a second conductive electrode having sidewalls that extend in the vertical direction to the first elevation level, and a switching barrier disposed between the first conductive electrode and the second conductive electrode and having sidewalls that extend in the vertical direction to the first elevation level, wherein the vertically extending sidewalls of the first conductive electrode, the second conductive electrode, and the switching barrier terminate at the first elevation level. The switching barrier includes ferroelectric (Fe) material that may be polarized to store information.

In certain embodiments of the memory device, wherein the heating structure and the FJT structure are formed in a BEOL (back-end-of-line) process.

In certain embodiments of the memory device, the switching barrier includes an Fe material plus an interfacial layer (IL) material.

In certain embodiments of the memory device, the Fe material is formed with sub 40 Å thickness.

In certain embodiments of the memory device, the Fe material includes perovskite, rutile, or orthorhombic thin film.

In certain embodiments of the memory device, the IL material is formed of a non-polar material with sub 20 Å thickness.

In certain embodiments of the memory device, the IL material includes SiO₂, Al₂O₃, Ta₂O₅, TiO₂, or TaON.

In certain embodiments of the memory device, the Fe material of the switching barrier is crystalized by heat emitted from the heating structure.

In certain embodiments of the memory device, the heating structure emits heat responsive to a current flow through the heating structure.

In certain embodiments of the memory device, the heating structure is a conductive electrode with a melting temperature greater than or equal to 800° C.

In certain embodiments, the memory device, further includes shallow trench isolation (STI) disposed between the heating structure and the FJT structure.

In certain embodiments of the memory device, the switching barrier is formed around parallel sidewalls of the first conductive electrode and along a bottom of the first conductive electrode to sandwich the first conductive electrode.

In certain embodiments of the memory device, the second conductive electrode is formed around parallel sidewalls of the switching barrier and along the bottom of the switching barrier to sandwich the switching barrier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A ferromagnetic tunnel junction (FTJ) device comprising:
a heating structure formed around an FJT structure on a plurality of sides;
the FJT structure comprising a first conductive electrode having sidewalls that extend in a vertical direction to a first elevation level, a second conductive electrode having sidewalls that extend in the vertical direction to the first elevation level, and a switching barrier disposed between the first conductive electrode and the second conductive electrode and having sidewalls that extend in the vertical direction to the first elevation level, wherein the vertically extending sidewalls of the first conductive electrode, the second conductive electrode, and the switching barrier terminate at the first elevation level;
wherein the switching barrier comprises ferroelectric (Fe) material that may be polarized to store information.

2. The FJT device of claim 1, wherein the heating structure and the FJT structure are formed in a BEOL (back-end-of-line) process.

3. The FJT device of claim 1, wherein the switching barrier comprises an Fe material plus an interfacial layer (IL) material.

4. The FJT device of claim 3, wherein the Fe material is formed with sub 40 Å thickness.

5. The FJT device of claim 3, wherein the IL material is formed of a non-polar material with sub 20 Å thickness.

6. The FJT device of claim 1, wherein the Fe material of the switching barrier is crystalized by heat emitted from the heating structure responsive to a current flow through the heating structure.

7. The FJT device of claim 1, wherein the switching barrier is formed around parallel sidewalls of the first conductive electrode and along a bottom of the first conductive electrode to sandwich the first conductive electrode.

8. The FJT device of claim 7, wherein the second conductive electrode is formed around parallel sidewalls of the switching barrier and along the bottom of the switching barrier to sandwich the switching barrier.

9. A semiconductor fabrication method comprising:
forming a first conductive electrode over an interconnection structure, the first conductive electrode having sidewalls that extend vertically to a first elevation;
forming a switching barrier within a gap in the first conductive electrode, the switching barrier having sidewalls that extend vertically to the first elevation, the switching barrier comprising ferroelectric material (Fe);
forming a second conductive electrode within a gap in the switching barrier, the second conductive electrode having sidewalls that extend vertically to the first elevation; and
heating the Fe material using a heater structure formed around a plurality of sides of the first conductive electrode to crystalize the Fe material, wherein the crystalized Fe material may be polarized to store information.

10. The method of claim 9, further comprising forming the heater structure, the first conductive electrode, the switching barrier, the second conductive electrode, and the heater structure in a BEOL (back-end-of-line) process.

11. The method of claim 9, wherein the switching barrier comprises an Fe material plus an interfacial layer (IL) material.

12. The method of claim 11, wherein the Fe material is formed with sub 40 Å thickness.

13. The method of claim 12, wherein the IL material is formed of a non-polar material with sub 20 Å thickness.

14. The method of claim 9, wherein the Fe material of the switching barrier is crystalized by heat emitted from the heating structure responsive to a current flow through the heating structure.

15. The method of claim 9, further comprising forming shallow trench isolation (STI) between the heating structure and the first conductive electrode.

16. A memory device comprising:
a transistor device;
a memory cell electrically coupled to a source or drain of the transistor device, the memory cell comprising an FJT structure;
a heating structure formed around the memory cell on a plurality of sides; and
the FJT structure comprising a first conductive electrode having sidewalls that extend in a vertical direction to a first elevation level, a second conductive electrode having sidewalls that extend in the vertical direction to the first elevation level, and a switching barrier disposed between the first conductive electrode and the second conductive electrode and having sidewalls that extend in the vertical direction to the first elevation level, wherein the vertically extending sidewalls of the first conductive electrode, the second conductive electrode, and the switching barrier terminate at the first elevation level;
wherein the switching barrier comprises ferroelectric (Fe) material that may be polarized to store information.

17. The memory device of claim 16, wherein the heating structure and the FJT structure are formed in a BEOL (back-end-of-line) process.

18. The memory device of claim 16, wherein:
the switching barrier comprises an Fe material plus an interfacial layer (IL) material;
the Fe material is formed with sub 40 Å thickness; and
the IL material is formed of a non-polar material with sub 20 Å thickness.

19. The memory device of claim 16, wherein the Fe material of the switching barrier is crystalized by heat emitted from the heating structure responsive to a current flow through the heating structure.

20. The memory device of claim 16, wherein:
the switching barrier is formed around parallel sidewalls of the first conductive electrode and along a bottom of the first conductive electrode to sandwich the first conductive electrode; and
the second conductive electrode is formed around parallel sidewalls of the switching barrier and along the bottom of the switching barrier to sandwich the switching barrier.
